(19) United States
(12) Patent Application Publication
(10) Pub. No.: US 2011/0108932 A1
(43) Pub. Date: May 12, 2011

(54) Micromechanical Capacitive Sensor Element

(76) Inventors: Hubert Benzel, Pliezhausen (DE); Stefan Finkbeiner, Gomaringen (DE); Frank Fischer, Gomaringen (DE); Helmut Baumann, Gomaringen (DE); Lars Metzger, Moessingen-Belsen (DE); Roland Scheuerer, Reutlingen (DE); Peter Brauchle, Nehren (DE); Andreas Feustel, Reutlingen (DE); Matthias Neubauer, Wannweil (DE)

(21) Appl. No.: 11/793,853

(22) PCT Filed: Nov. 4, 2005
(86) PCT No.: PCT/EP2005/055755

§ 371 Date: Mar. 6, 2009

(30) Foreign Application Priority Data
Dec. 22, 2004 (DE) 10 2004 061 796.1

(51) Int. Cl. H01L 29/84; H01L 21/02

(52) U.S. Cl. 257/415; 438/53; 257/E21.002; 257/E29.324

(57) ABSTRACT

A manufacturing method for producing a micromechanical sensor element which may be produced in a monolithically integrable design and has capacitive detection of a physical quantity is described. In addition to the manufacturing method, a micromechanical device containing such. a sensor element, e.g., a pressure sensor or an acceleration sensor, is described.

### FIELD OF THE INVENTION

The present invention is directed to the manufacture of a capacitive sensor element produced micromechanically in a monolithic design and a micromechanical device having such a sensor element, having at least one first electrode and one second electrode, a diaphragm and a cavity.

### BACKGROUND INFORMATION

Capacitive surface micromechanical (SMM) pressure sensors are known in various embodiments. In contrast with piezoresistive sensors, capacitive sensors have the advantage that they are capable of analyzing the measuring capacitances contained therein using virtually no power. This is due mainly to the fact that they avoid the use of stress detectors in the form of piezoresistors through which high currents would otherwise flow. Furthermore, capacitive pressure sensors offer the advantage that they are largely independent of temperature.

For many applications, it is desirable to have capacitive pressure sensors (or other capacitive sensor elements) which may be designed to be monolithically integrated as part of an IC manufacturing process, e.g., a CMOS process.

Capacitive pressure sensors usually have a cavity bordered by two electrodes, one electrode being formed by an elastic, electrically conducting diaphragm and the other electrode being formed by a capacitor plate opposite the electrically conducting diaphragm. A pressure difference between the pressure prevailing in the cavity and the outside pressure results in bending of the diaphragm and thus a change in the distance between the electrically conducting diaphragm and the capacitor plate opposite this diaphragm. The outside pressure acting on the capacitive pressure sensor is determined from the change in capacitance associated with this in the capacitor formed from the electrically conducting diaphragm and the capacitor plate. Such a typical capacitive pressure sensor is known from European Patent Publication No. EP 0 714 017, in which the cavity between two electrodes is manufactured by sacrificial layer etching.

German Patent Publication No. DE 101 21 394 describes a capacitive pressure sensor having a second electrode which largely surrounds the first electrode and is at the same electric potential. This achieves the result that the electric field, i.e., the measuring field, prevailing between the (third) diaphragm electrode and the first electrode of the capacitive pressure sensor is largely shielded with respect to electric interference fields that may surround a micromechanical pressure sensor. This largely suppresses any influence on the capacitance to be detected as a measure of the pressure detected.

German Patent Publication No. DE 40 041 79 A1 describes an integrable capacitive pressure sensor in which a first electrode in a semiconductor substrate and a second electrode are created by deposition and doping of a polycrystalline semiconductor layer. A spacer layer is applied, defining the subsequent pressure sensor cavity. This spacer layer is removed by an etching operation at a subsequent point in time.

### ADVANTAGES OF THE INVENTION

The present invention describes a manufacturing method for creating a micromechanical sensor element that may be produced in a monolithically integrable design and has capacitive detection of a physical quantity. In addition to the manufacturing method, a micromechanical device containing such a sensor element, e.g., a pressure sensor or an acceleration sensor, is also described. According to the present invention, the manufacturing method includes various method steps, at least one first electrode being produced in or on the semiconductor substrate.

In addition, a first layer is applied to the first electrode, the first layer in particular also covering parts of the semiconductor substrate or an insulation layer which is beneath the first electrode and extends laterally beyond the first electrode. A first sacrificial layer is then applied, which has a first sacrificial material and is produced on the semiconductor substrate at least partially above the first electrode. A second layer is then applied to the first sacrificial layer, a first through hole being created therein, thereby creating access to the first sacrificial layer. A second electrode is applied to the second layer. The first through hole is sealed using a second sacrificial material, forming a second sacrificial layer, preferably on the second layer. The diaphragm layer is then applied to the second electrode and at least to a portion of the second layer adjacent to the second electrode. The second sacrificial layer may also be covered. A second through hole is then created in the diaphragm layer, permitting access to the second sacrificial layer. The second and first sacrificial materials may be dissolved through the second through hole and following that through the first through hole. This is preferably accomplished by a plasmaless etching process. Next a third layer is applied to the diaphragm layer, sealing at least the second through hole and thus creating a cavity in the area of the first sacrificial layer between the first and second electrodes.

The significant advantage in comparison with the known related art is the separation of the mechanical function of the diaphragm from the electric function of the upper capacitive electrode. In addition, the upper capacitive electrode may be formed by a thin conductive film which may be deposited at moderate temperatures and structured independently of the diaphragm layer. The etching process may be terminated in a controlled manner through the use of the two sacrificial layers. Furthermore, dry plasmaless sacrificial layer etching prevents etching residues from being left behind.

It is also advantageous to apply an insulating layer to the semiconductor substrate before creating the first electrode.

This prevents leakage currents that could falsify the test signal from occurring on the first electrode during the measurement operation. Such leakage currents may occur at a pn-type junction, for example, when an n-type electrode is produced in a p-type substrate. Furthermore, in the case of a first electrode insulated from the substrate, it may be at any potential without regard for interaction with the substrate.

In a refinement of the present invention, the first electrode may contain an n-type or p-type conducting doped semiconductor or polysilicon. In addition, at least the first or second layer may also contain an oxide, nitride or TEOS. Although Si or SiGe may be provided for the first sacrificial material, SiGe or polysilicon is provided for the second sacrificial material. In addition, the second electrode may also contain Si, SiGe or polysilicon, while the diaphragm layer preferably contains nitride, oxide or a dielectric material. Finally, the third layer may contain nitride.

The first layer advantageously has a layer thickness of 40 nm to 250 nm, the first sacrificial layer has a layer thickness of 0.3 μm to 1 μm, the second layer has a layer thickness of 50 nm to 250 nm and the diaphragm layer has a layer thickness of 100 nm to 1000 nm. On the whole, a layer stack having minimal topography may be produced by using these thin layers. For example, layer stacks thinner than 1.7 μm and having a topography of <0.5 μm are conceivable.

To seal the second through hole, the layer thickness of the third layer should be greater than the layer thickness of the second sacrificial layer. Enough material may thus be provided to seal the second through hole.

To achieve the most planar and uniform possible diaphragm layer, the layer thickness of the second sacrificial layer may be selected as a function of the layer thickness of the second electrode. Both layers may be applied in the same thickness here in particular.

The micromechanical sensor element is advantageously manufactured as part of a standard IC process (e.g., a CMOS process). Circuit parts that are used for contacting the sensor element and for detecting and/or analyzing the sensor signals of the sensor element may be produced on the sensor element. As a classical micromechnical process, sacrificial layer etching may under some circumstances be shifted to the end of the process (before passivation). Therefore, no cavity would have to be processed in the CMOS line because the operations of sacrificial layer etching, passivation and, if necessary, opening the passivation for contacting the sensor element may be performed by the micromechanical process. Furthermore, there would not be any movable part in the CMOS processing line, so the risk due to particles is reduced.

The manufacturing method proposed here allows production of a capacitive sensor element having a reduced parasitic capacitance by at least one order of magnitude in comparison with known sensor elements. This permits a high signal-to-noise ratio, thus also requiring less area for the sensor element. Furthermore, the reduced parasitic capacitance results in reduced current consumption for the analytical circuits. One possibility of further reducing the parasitic capacitances is to increase the insulation distance between the two electrodes. In addition to selecting a thicker first sacrificial layer, this may also be accomplished by applying a fourth insulating layer between the first and second layers, and in particular this fourth layer may be situated only partially between the first and second electrodes. However, it is particularly advantageous if the fourth layer is applied next to the first sacrificial layer and has a layer thickness comparable to that of the latter. Therefore, the third layer may be produced without a pronounced step at least in the area of the first and/or second electrodes.

In a special embodiment of the present invention, the plasmaless etching process for dissolving the first and second sacrificial layers is performed with a fluorinated etching material such as ClF₃ and/or XeF₂. By using a plasmaless etching process, the two sacrificial layers may be dissolved away after producing circuit elements by a CMOS process. Heat damage to thin printed conductors within such circuit elements may thus be avoided. Such etching processes may typically be used at temperatures between −20° C. and 60° C.

In general, the layers of the sensor elements described here may be produced using standard equipment. The layer tension of the diaphragm may be adjusted by using an RTA process (rapid thermal annealing process) if necessary.

In addition to the sensor element, a reference measuring element may be produced on the semiconductor substrate, advantageously also by the method of the main claim described here. According to the present invention, in the first sacrificial layer of the reference element, at least one third through hole which permits access to the first layer is produced in the first sacrificial layer of the reference element to form support points for the diaphragm. In a refinement of the present invention, this at least one third through hole may then be filled with the material of the second electrode and/or with the material of the diaphragm layer. After dissolving out the first and second sacrificial layers, a cavity is formed beneath the diaphragm, which stands on posts in comparison with the sensor element. Movement of the diaphragm may thus be reduced, if not prevented entirely. The residual movement of the diaphragm of course depends on how many through holes and/or support points/posts are produced and how they are distributed spatially in the interspace between the two electrodes.

Shielding of the measuring electrode(s) against external interference fields may be achieved by an additional conductive layer that forms a third electrode over the entire sensor element (Faraday cage). Such a third electrode may include, for example, an additional polysilicon layer or a metal layer. In combination with the CMOS process, the layer may also include a CMOS metal level. To avoid possible temperature effects, the shielding electrode may be structured like a mesh grating, for example. However, a shielding effect may also be achieved by keeping the second (upper) electrode at ground potential.

In another embodiment of the present invention, a mass element having a defined seismic mass in particular is applied to the diaphragm and/or a passivation layer adjacent to the diaphragm above the first and second electrode. The mass element may be produced by a local deposition method, a dispensing method, a screen printing method or a known micromechanical structuring method.

With such a mass element on the diaphragm, an acceleration sensor may be produced in a simple design using a capacitive sensor element. The sensitivity may be adjusted easily through the choice of mass and also through the triggering and analysis of the two electrodes, e.g., by an offset adjustment in initializing the sensor element. By using multiple diaphragm cells having mass elements of different weights, it is also possible to cover a greater bandwidth of possible acceleration values. Each diaphragm cell advantageously includes two electrodes, a cavity between the electrodes and a diaphragm, a supporting device being provided in the cavity to prevent the diaphragm from breaking when there is excessive sagging.

Such an acceleration sensor eliminates the need for expensive capping of otherwise conventional acceleration sensors to protect them before sawing, separation and/or assembly. Simple adjustment of the sensitivity is also possible through a defined choice of mass, and multi-channel elements may also be produced easily, as shown here.

In general, by combining CMOS processes and micromechanical method steps to produce the sensor element according to the present invention, the layers and levels may be coordinated mutually and thus used jointly. This yields a more efficient and therefore less expensive manufacturing operation.

The capacitive sensor elements according to the present invention may also advantageously be used at high temperatures by using polysilicon electrodes separated by oxide layers from the substrate and from other layers. This has advantages, for example, when used as tire pressure sensors because a low power consumption is also required, and as combustion chamber pressure sensors.

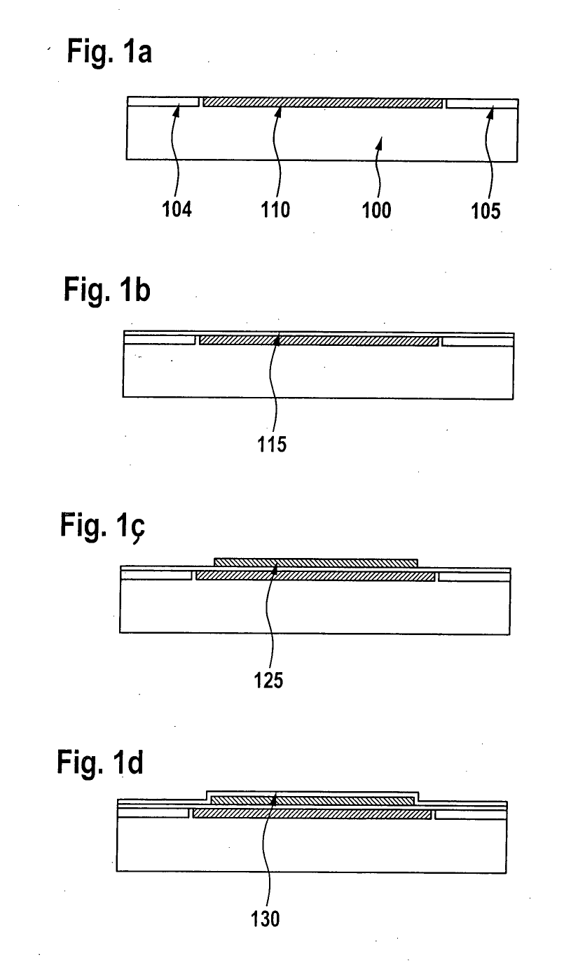

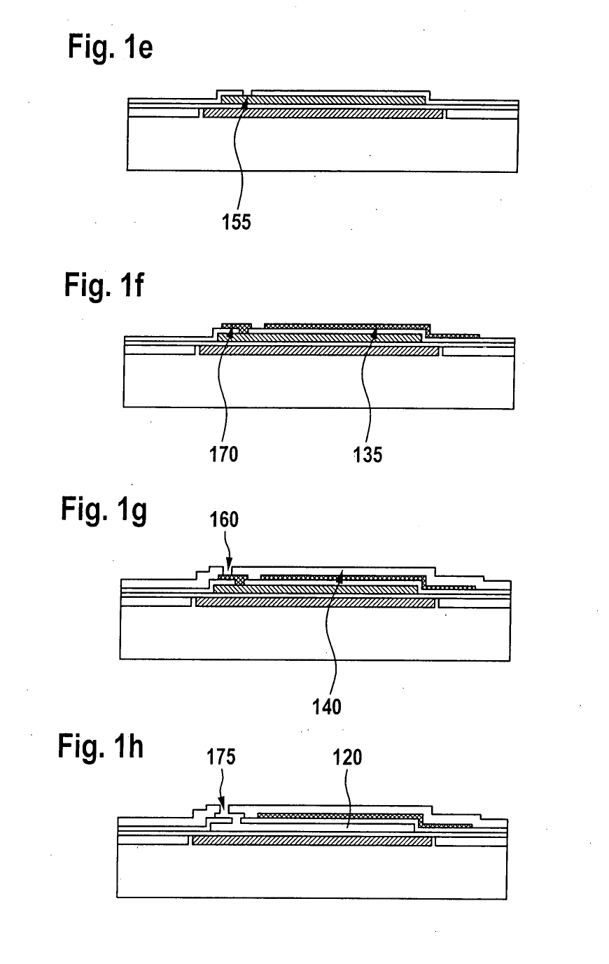

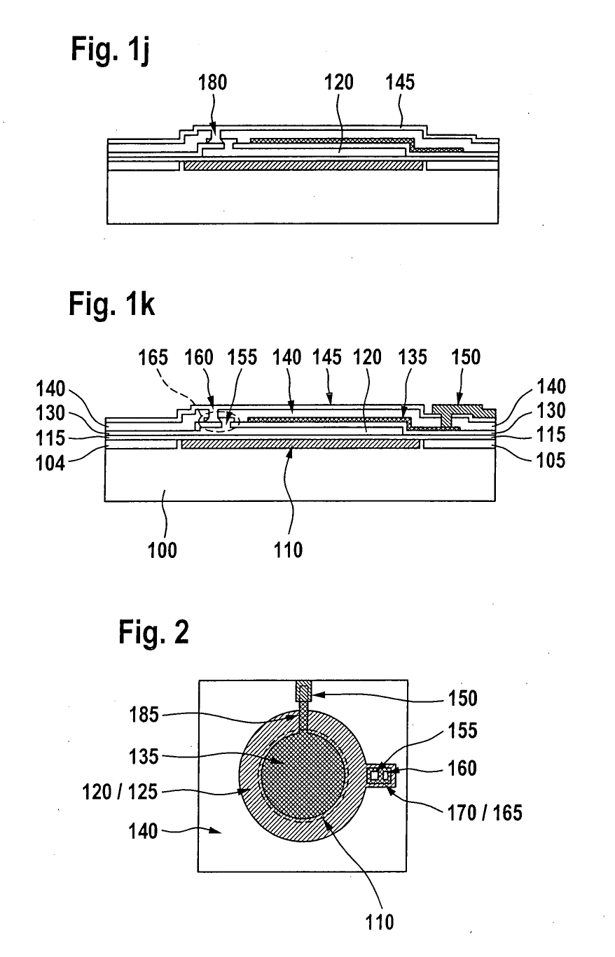

FIGS. 1a through k show method steps for producing the capacitive sensor element according to the present invention.

FIG. 2 shows a top view of the capacitive sensitive element.

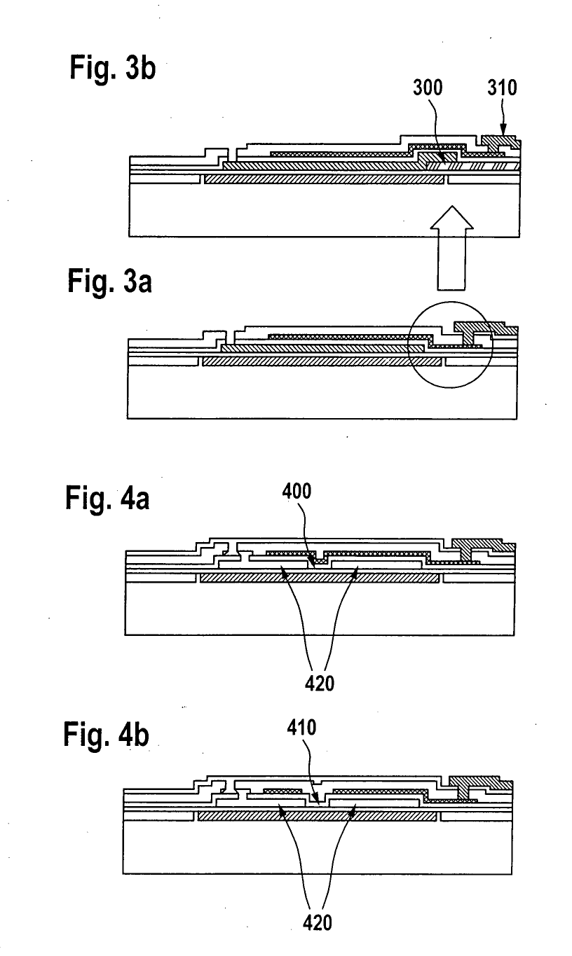

FIGS. 3a and b show insertion of an additional insulation layer.

FIGS. 4a and b show a reference element having supporting posts.

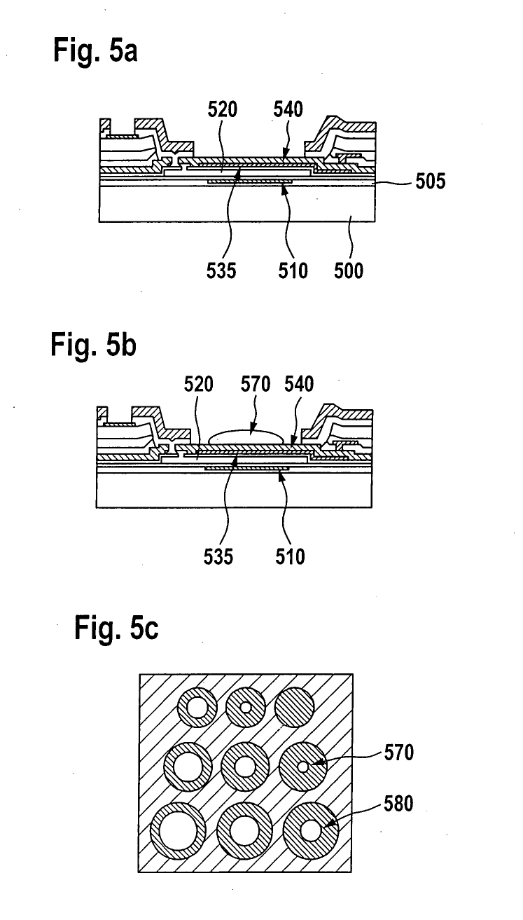

FIGS. 5a through c show an acceleration sensor.

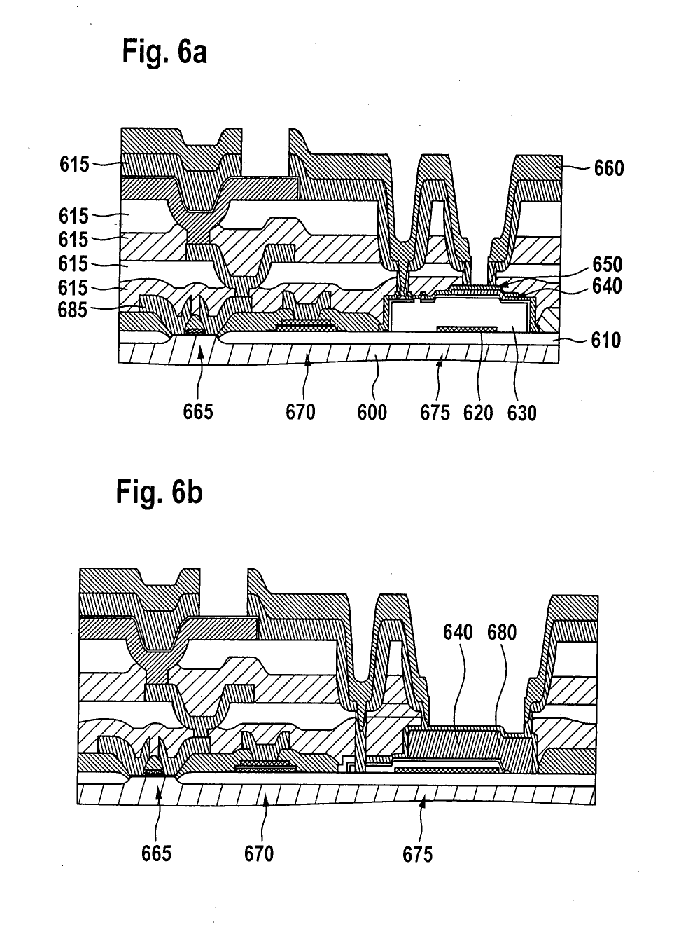

FIGS. 6a and b show a change in the clamping of the diaphragm.

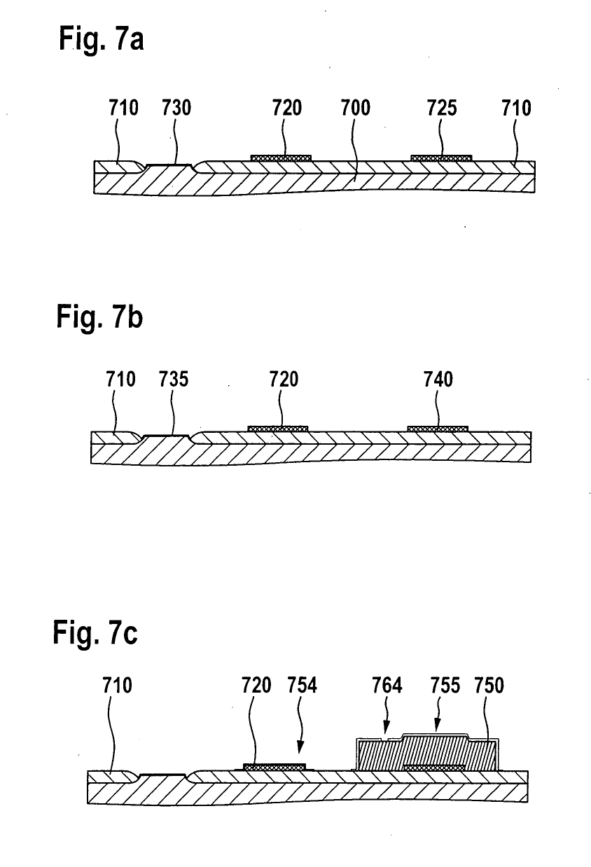

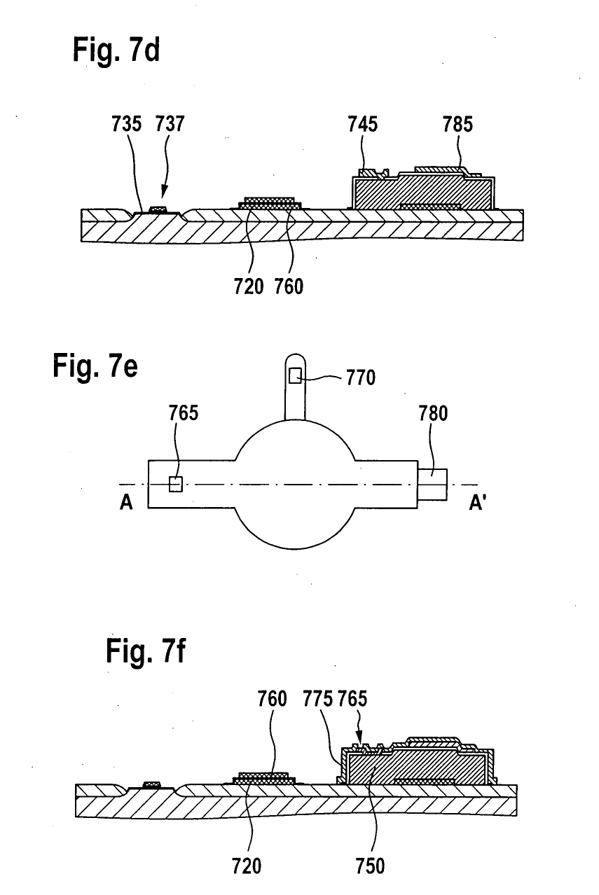

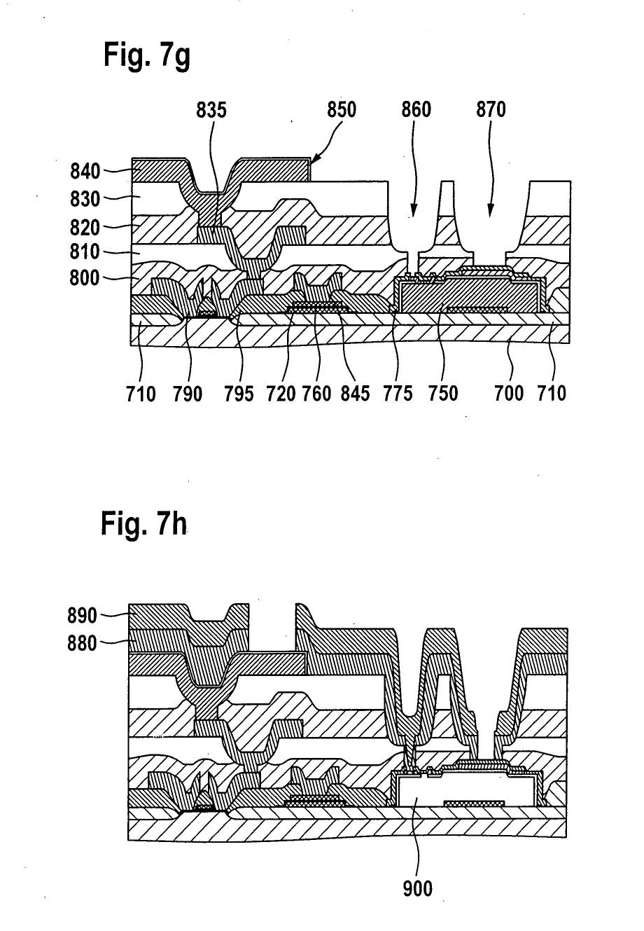

FIGS. 7a through h show an alternative process sequence for producing a capacitive sensor element according to the present invention.

### DETAILED DESCRIPTION

FIGS. 1a through k illustrate a possible manufacturing process for a monolithically integrated capacitive sensor element according to the present invention using micromechanical method steps. According to FIG. 1a, first electrode 110 is created in or on semiconductor substrate 100 by n-doping, for example. In addition, terminal regions 104 or insulation regions 105 may be created in or on semiconductor substrate 100. In other regions of the semiconductor substrate, gates may be formed using gate oxide, poly, etc.

FIG. 1b shows first layer 115 having a thickness of 40 nm to 250 nm applied to the entire circuit. The first layer is deposited at temperatures <900° C. and serves to protect first electrode 110 and/or regions 104 and/or 105 from attack by ClF₃, XeF₂ or the like. First layer 115 is preferably made of oxide or nitride, but is preferably a TEOS layer applied to the surface at 400° C. with ozone support in a preferred thickness of 100 nm. When using thermal oxide (e.g., thick gate oxide) for first layer 115, 40 nm (or less) is sufficient. In addition to insulating first electrode 110, the main use of first layer 115 is to protect against the subsequent plasmaless etching, e.g., by ClF₃. Therefore, one requirement of first layer 115 is that it must be tight and resistant to the etching materials used in this process.

As shown in FIG. 1c, first 0.3 μm to 1 μm thick sacrificial layer 125 of Si or SiGe is deposited on first layer 115. This is done using a deposition method that may be performed at temperatures below 900° C. First sacrificial layer 125 may be deposited using PECVD as an amorphous or partially crystalline Si layer, but preferably using LPCVD at a temperature <680° C. with a layer thickness of 450 nm to 550 nm. It is important to be sure that the surface roughness (Rₐ) of first sacrificial layer 125 is less than 100 nm. First sacrificial layer 125 is subsequently structured so that at least a portion of first sacrificial layer 125 is above first electrode 110. On the remaining surface, however, first sacrificial layer 125 may be removed. The structuring step, i.e., the lithography technique, is preferably performed in such a way that no sharp edges are formed but instead relatively soft structure flanks are formed. This permits a further increase in stability of the pressure diaphragm under extreme pressure overloads.

FIG. 1d shows the production of second layer 130, which is deposited over the entire surface of first sacrificial layer 125 and the remaining surface of the substrate. Second layer 130 is preferably between 50 nm and 250 nm thick and is deposited at temperatures below 900° C. A layer resistant to the subsequent plasmaless etching process is to be produced using this second layer 130 of nitride or oxide. Another option is to form second layer 130 from a 100-nm-thick ozone-supported TEOS layer. Such TEOS:O₃ layers generally have dense surfaces and a resistance to ClF₃ etching. In addition, such layers have very good edge coverage and also have the property of very efficiently smoothing out surface roughness, partially compensating for the roughness of first sacrificial layer 125. It is also advantageous, although not obligatory, if the layer tension of second layer 130 is low and/or second layer 130 has a low tensile stress. If a difference in thermal expansion coefficients between second layer 130 and diaphragm layer 140 yet to be applied results in an unwanted drift in temperature sensitivity and/or in the sensor offset, the second layer may be made of the same material as diaphragm layer 140 (e.g., both may be made of LPCVD nitride).

To obtain access to first sacrificial layer 125 for the subsequent etching process, first through hole 155 is created in second layer 130, e.g., by a suitable dry etching method in another method step (see FIG. 1e). First through hole 155 may be created in one or more locations in second layer 130. In structuring second layer 130, the etching process ends at first sacrificial layer 125, but it does not harm the remaining process flow if a portion of first sacrificial layer 125 in the area of first through hole 155 is also attacked by the etching process and dissolved. Under unfavorable etching conditions, the etching process may also be time-controlled. In general, it is important to be sure that in structuring, i.e., creating first through hole 155, the edges of first sacrificial area layer 125 remain sufficiently well covered with photo-resist to prevent uncontrolled attack at the structure flanks of second layer 130.

In the next method step (see FIG. 1f), an electrode layer is deposited on second layer 130 to form second electrode 135. The electrode layer is preferably made of polysilicon, which is produced by a suitable method at moderate temperatures below 900° C. and is rendered conductive. The conductivity of second electrode 135 need not be very high to fulfill the desired function in the capacitive sensor element. One option for making the electrode layer conductive is to produce the layer by doping by ion implantation. The required healing step may then be combined with annealing for lower poly layers from CMOS processing (e.g., poly gate). However, this electrode layer 135 may also be made of metal, in which case a different sealing technique than that described below must be used.

When using polysilicon or poly SiGe as the material for second electrode 135, a poly sheet may be produced at the same time with the electrode layer in the area of first through hole 155 and may then later be used as the etching access for the subsequent plasmaless etching process. In general, second sacrificial layer 170 of a second sacrificial material is produced, filling both first through hole 155 and also covering a portion of second layer 130 situated next to first through hole 155. Therefore, an offset etching access 175 having access to first sacrificial layer 125 may be produced with a second through hole 160 (see FIGS. 1g and 1h). The layer thickness of the second sacrificial layer is preferably adapted to the layer thickness of the first sacrificial layer to prevent steps on the surface of the diaphragm layer.

As shown in FIG. 1g, diaphragm layer 140 is applied over the electrode layer to form second electrode 135; together with second layer 130 and third layer 145 to be applied subsequently, this establishes the bearing function of the diaphragm. Diaphragm layer 140 is therefore designed for tensile stress at deposition temperatures <900° C. Due to the preferred choice of LPCVD nitride as the material of diaphragm layer 140, it may be designed to be resistant to the plasmaless etching process. In addition, however, it is also possible to use other nitride or oxide layers that may be deposited in a reproducible manner with regard to tensile strength and layer thickness. In general, diaphragm layer 140 may be produced in a layer thickness of 100 nm to 1 μm, a layer thickness of 200 nm to 500 nm being sufficient in the case of LPCVD nitride. To improve the resistance of diaphragm layer 140 to plasmaless etching, a very thin oxide layer (not shown) may be deposited on diaphragm layer 140. To prepare for dissolving out the first and second sacrificial materials, i.e., the first and second sacrificial layers, a second through hole 160 is created in diaphragm layer 140, leading to the second sacrificial layer and having an opening that is offset in relation to first through hole 155. This opening 160 establishes etching access 175 to first sacrificial layer 125 through second sacrificial layer 170 and first through hole 155. It has been found in experiments that plasmaless etching using ClF₃ has reaction-limited etching rates and is almost independent of the layer thickness of the sacrificial poly layer. However, when using XeF₂, transport-limited etching rates have been observed which greatly depend on layer thickness. Etching rates on very thin layers are thus increased by up to 800% in comparison with layers >20 μm thick. The thickness of the two sacrificial layers thus does not have any negative effect on sacrificial layer etching with the layer thicknesses used in the present method.

In sacrificial layer etching using ClF₃ or XeF₂, all exposed polysilicon layers are etched very rapidly (see FIG. 1h). The back of the substrate may, but need not, be protected with an oxide or nitride. ClF₃ goes through “etching valve” 175 to sacrificial layers 170 and 125 and removes the polysilicon, i.e., the sacrificial material, in both layers at rates of up to 10 μm/min. A temperature of −20° C. to 60° C. may be used during the etching step due to the plasmaless etching process using ClF₃, so there is no damage to circuit parts already processed in a previous CMOS process. In addition, protective layers of photo-resist may also be used to protect certain areas.

Since Al is not etched by ClF₃, the sacrificial layer etching process may also be performed after deposition and structuring of the last metal level in the CMOS process. In this exemplary embodiment, at first no cavity is created that would otherwise have to be protected during CMOS wiring. This eliminates the risk of mechanical damage due to process handling and/or ultrasonic cleaning. In this exemplary embodiment, the cavity is created and sealed at the end of the CMOS process by the last passivation step, which seals etching access 175.

In general, according to FIG. 1j, etching access 175 may be sealed by a third layer 145 at temperatures of <900° C. In doing so, second through hole 160 is filled with the material of third layer 145, forming a stopper 180 that encloses a definable reference pressure prevailing in cavity 120 at the time of sealing the cavity. The lateral offset of the two through holes prevents the material of third layer 145 from penetrating into cavity 120 and filling it. If the layer thickness of third layer 145 is selected to be slightly larger than the layer thickness of the second sacrificial layer, the result is that etching access 175 is hermetically sealed because a sufficient amount of material is available, since deposition of third layer 145 and the edge coverage, i.e., wraparound, of the deposition results in a large-area seal having an adequate sealing depth. An LPCVD process or a PECVD process may be used for third layer 145. Third layer 145 is preferably made of nitride having a low defect density, which is known to have a good long-term stability based on the airtightness. Finally, another reinforcement of the seal may be achieved in area 180 in one of the metal levels of the CMOS process.

After sealing cavity 120, the wiring levels in the CMOS process are further created. As one approach, FIG. 1k shows a metal pad 150 which is connected to second electrode 135 through a contact hole through diaphragm layer 140 and third layer 145. However, first electrode 110 has been contacted through an earlier CMOS method step (not shown). If sacrificial layer etching was performed after the last metal processing level, the contact must first be sealed in advance. The passivation formed by third (sealing) layer 145 is then on metal pad 150 and must be opened.

FIG. 2 shows a schematic view of a capacitive sensor manufactured by the method described here having first electrode 110, sacrificial poly layer 125 situated above the former (and/or cavity 120), second electrode 135 and diaphragm layer 140 situated above the latter and designed to be self-supporting in the area of first sacrificial layer 125 by sacrificial layer etching. Second electrode 135 is guided over a printed conductor 185 next to the self-supporting diaphragm, where it may be connected to a metal strip and/or a metal pad 150. Etching valve 175 is shown in the area at the right in FIG. 2.

With the present exemplary embodiment of the present invention, parasitic capacitances may be reduced in comparison with the known approaches in the manufacture of capacitive sensor elements. This is due, among other things, to the fact that only a very narrow printed conductor 185 leads away from the diaphragm and the upper electrode is not connected over the full extent of a very broad support via the outer connecting regions in the substrate, as is the case with the known capacitive sensors, because the electrode also forms the bearing diaphragm construction with the known sensors. In addition, the insulation distance, made up of layers 115 and 130, may be selected to be much larger with the present capacitive sensor element. In addition, another insulation layer 300 (see FIG. 3b in comparison with FIG. 3a) made of oxide or nitride over first layer 115 may also be used to further increase the insulation distance. It may be advantageous to insert this insulation layer 300 only in the area of contact 310 and/or to adjust the layer thickness thereof to the layer thickness of first sacrificial layer 125.

In another exemplary embodiment, a reference element may also be created in addition to the capacitive sensor element already described. For the design of a reference element with the help of which the offset of the sensor may be determined, for example, through holes to first layer 115 are created within first sacrificial layer 125. Non-positively connected but electrically insulated supports 400 and/or 410 may be formed beneath the pressure diaphragm with these through holes, mechanically connecting the diaphragm to the substrate. Cavity 420 supported by supports, i.e., posts, is thus created by sacrificial layer etching. As shown in FIGS. 4a and 4b, the electrode material of second electrode 135 may be integrated into the recess of support 400 or a corresponding recess may be provided, so that support 410 causes a lower interference capacitance than support 400.

Another exemplary embodiment is depicted in FIGS. 6a and 6b as an example. These figures show several micromechanical sensor elements produced using a combination with a CMOS process. The figures show CMOS transistor 665, CMOS capacitor 670 and sensor element 675 described according to FIGS. 1a through 1k. The essential difference between the sensor element of FIG. 1k and sensor element 675 according to FIG. 6a, however, is that insulating (oxide) layer 610 has been applied to (semiconductor) substrate 600, largely insulating, thermally and/or electrically, the lower electrode, i.e., first electrode 620, from substrate 600. This makes it possible to prevent an effect on measurement results, e.g., due to a leakage current into the substrate. In addition, the potential may be selected at will for this first electrode 620 due to the use of such an insulating layer 610. Moreover, sensor element 675 also has a cavity 630 between first electrode 620 and second electrode 640 above it, both made of polysilicon, for example. Supporting structure 650 of second electrode 640 is preferably made of nitride so that, like the sensor element according to FIG. 1k, there is a separation here between the mechanical function of the diaphragm and the electric function of the second, upper capacitance electrode.

The design according to FIG. 6a shows multiple layers that are not explained in greater detail below. These include mainly insulating oxide layers 615 and metal layers 685 which are used for the function of individual micromechanical components 665, 670 and 675 or function strictly as contacts. In conclusion, with such a layer sequence, the layers, i.e., the metal levels, thus produced are usually protected from environmental influences by using a passivation layer 660 made of nitride, for example. In addition to supplying the medium onto the diaphragm, certain surface areas of the layer stack may also remain open as contact points for external circuits.

A further improvement, i.e., stabilization, of the detection of measured values by the capacitive sensor element described here is achievable by using shielding. Such shielding makes it possible to reduce the effect on the test signal due to external interference fields, external objects, dirt or other layers during the manufacturing process. To this end, the external electrode, i.e., second electrode 640 of the sensor element, may be at ground potential, e.g., by connecting it electrically to the substrate wafer or by low-resistance clamping. This shields the lower electrode, i.e., first electrode 620, from external interference fields (Faraday cage). Measuring capacitor 675 formed by the two electrodes may then be analyzed, e.g., by applying a charge to lower electrode 620 and then converting this charge into a voltage signal by a charge amplifier (switched capacitor circuit). This output voltage is proportional to the capacitance of measuring capacitor 675. Due to the shielding effect, the sensor chip is independent of external interference fields as well as external objects which have different dielectric values or are conductive. Such objects may include, for example, dirt, additional layers in the process or the sensor housing. A shielded capacitor is also insensitive to external proximity or media coming in contact with the sensor, because these influences are unable to affect the field of the measuring capacitor.

Another possibility of achieving shielding is to apply an additional conductive layer over the entire pressure measuring capacitor. Such a layer may be, for example, another polysilicon layer or a metal. In conjunction with the CMOS process, the layer may be one of the CMOS metal levels. To prevent possible temperature effects, the shielded electrode may be structured like a mesh grating, for example.

The function of the capacitive sensor element depends to a great extent on the different thermal expansion coefficients of the various layers of the diaphragm and the clamping of the diaphragm. Layer stress causes bulging of the diaphragm, which is superimposed on the actual test signal. If materials of approximately the same thickness are used for the diaphragm, the layer stress has a particularly great effect (bimetal effect). The diaphragm enclosure also has a great influence on sensor function. The same effects as described for the diaphragm also occur in the area of the clamping of the diaphragm. If the geometry of the enclosure changes as a function of temperature, then force and torque along the attachment also change. This results in interfering deflection of the diaphragm as a function of temperature. Although this may be mostly compensated in the analyzer circuit, this is complicated in the case of high-temperature effects and is associated with additional costs.

FIG. 6b illustrates an exemplary embodiment in which the negative effect of the clamping of the diaphragm is reduced. The diaphragm is defined by the greater thickness mainly due to polysilicon. The layers above and below polysilicon layer 640 are approximately symmetrical in structure so the stress is compensated. The diaphragm in FIG. 6b is clamped only by the diaphragm material at the edge, with the diaphragm edge being defined by the cavity beneath it. The diaphragm is thus defined by the lateral border of the first sacrificial layer and/or the cavity, so that thermally induced changes in length due to different thermal expansion coefficients no longer have any influence. In addition, the clamping 680 of the diaphragm is not disturbed by any other materials. The polysilicon diaphragm is connected to the bulk silicon, which has the same thermal expansion coefficient, only by an oxide layer.

An alternative possibility of removing the various oxide and nitride layers over the diaphragm is for BPSG (not shown) to be deposited instead of nitride over second upper electrode 640. BPSG is the next insulation layer deposited in the CMOS process. If the first metal (e.g., 685) is not etched away on the diaphragm, it may be used as an etching stop in conclusion in etching the oxide and nitride layers. The metal is then removed and the passivation is deposited. As another embodiment, the polysilicon diaphragm according to FIG. 6b may also be used as an etching stop layer in etching the oxide-nitride stack.

In another exemplary embodiment, the micromechanical capacitive sensor element according to the present invention as illustrated in FIG. 5a is used as the starting element for producing an acceleration sensor. In addition to first electrode 510, second electrode 535, cavity 520 between the electrodes and diaphragm 540, which are already known, an insulation layer 505 as already mentioned has been applied to (semiconductor) substrate 500. To implement the acceleration sensor, mass element 570 has been applied to diaphragm 540 as illustrated in FIG. 5b. Due to the increased weight of the diaphragm, the sensor element becomes sensitive to accelerations, i.e., it may be used mainly perpendicular to the plane of the chip. In this spring-weight system, the rigidity is determined by the expansion and mechanical properties of the diaphragm. If three such acceleration sensors are each operated at right angles, it is possible to cover all directions in space.

Mass element 570 having a defined mass may be applied after completion of the integrated capacitive diaphragm sensor. Local deposition methods may be used for this such as those known in the inkjet printing method from DE 103 15 963 A1. It is also conceivable to use dispensing methods in which tiny quantities of lacquers may be applied in a controlled manner. In addition, however, known screen printing methods may also be used. Deposition may be performed in the tempering step in which the applied substance is hardened. Simple dyes, lacquers, polymers, suspensions or similar materials processable in a controlled manner may be used as the substance for mass element 570.

Alternatively, a layer may also be applied over the entire area and may be structured by a known (micromechanical) masking method in a subsequent step so that a defined mass element 570 remains standing over dielectric diaphragm 540.

FIG. 5c illustrates the distribution of mass elements 570 and 580 having different masses over a plurality, of diaphragm cells. The sensitivity of the inertial sensor may be determined by the lateral dimension and the distribution of the mass of the capacitive sensor diaphragm. In this way, low-g to high-g applications may be covered with sufficient accuracy. A high overload withstand capability is achieved due to the diaphragm form of the spring. Transverse accelerations in the x and y directions (in plane with the chip) have a slight effect on the sensor signal. A high overload protection may additionally be achieved by the fact that the diaphragm may be contacted in the event of an overload, so the center of the diaphragm is supported.

Another exemplary embodiment is illustrated in FIGS. 7a through h. With this exemplary embodiment, another process is described in which a pressure sensor element and a CMOS analyzer circuit are integrated monolithically on a substrate. By utilizing synergisms in the layer sequence of the pressure sensor element and the CMOS analyzer circuit, only a few additional layers and photolithography steps are necessary in comparison with the CMOS process to manufacture the sensor element.

The basis for the process flow to be described in conjunction with FIGS. 7a through h is a CMOS process in which a pressure sensor element 675 having a dielectric diaphragm and an embedded polysilicon electrode is formed by insertion of a silicon-containing sacrificial layer before the metal layers of the CMOS process. This is made possible by, among other things, a silicon sacrificial layer etching step using ClF₃ and by separation of the mechanical and electric functionalities of the diaphragm layer. The process flow is therefore optimized from the standpoint that the steps modified in the CMOS process cause little or no change in the functionality of the CMOS circuit elements (transistor 665, capacitor 670).

The starting point for the process is a (semiconductor) substrate 700 onto which an approximately 700 nm thick structured LOCOS layer 710 is deposited for thermal and electric insulation, as illustrated in FIG. 7a. For the lower electrode of the capacitor, an approximately 300 nm thick layer 720 is formed on this LOCOS layer 710, and for the lower electrode of the pressure sensor element, a layer 725 of polysilicon in an equivalent thickness is formed. To form the subsequent transistor, an approximately 40 nm thick sacrificial oxide layer 730 (the layer from which gate oxide 735 is formed subsequently) is produced on substrate 700. Layer 740 of gate oxide is applied to layer 725 as illustrated in FIG. 7b, separating the lower electrode of the pressure sensor element from sacrificial layer 750 which contains silicon and is deposited in the following step (see FIG. 7c). Due to the gate oxide, lower electrode 725 is passivated for the subsequent ClF₃ etching attack. An approximately 1000 nm thick poly-O layer 750 is used as the sacrificial layer in the present exemplary embodiment. The thickness of layer 750 depends on the desired sensitivity range but is typically on the order of magnitude of 1 μm to prevent excessive additional topography. An ONO layer system 755, which is created in the CMOS process by thermal oxidation, deposition of SiN and reoxidation, surrounds sacrificial layer 750 and separates sacrificial layer 750 from the upper electrode of the pressure sensor element. In the same method step, ONO layer system 754 which functions as a dielectric may also be applied to the lower electrode of CMOS capacitor 670. In structuring ONO layer 755, etching access 764 to sacrificial layer 750 is exposed. The gate oxide is formed, and then is immediately protected by a thin polysilicon layer (thin poly). After deposition of the thin poly layer, an additional lacquer and etching step is performed, exposing etching access 764 to silicon-containing sacrificial layer 750. As shown in FIG. 7d, a second approximately 300 nm thick polysilicon layer is then, forming both gate electrode 737 of transistor 665 and upper electrode 760 of capacitor 670 in the CMOS process. In addition, upper electrode 785 of pressure sensor element 675 is produced with this second polysilicon layer, and in combination with the lower electrode, it defines the electric functionality of the pressure sensor. At the same time, etching access 764 is sealed with a polysilicon layer 745 through which subsequent etching access to sacrificial layer 750 is achieved. FIG. 7f illustrates the three elements (transistor 665, capacitor 670 and pressure sensor element 675) in cross section after deposition and structuring of an approximately 200 nm thick SiN layer 775. Second etching access 765 to second polysilicon layer 745, forming the etching channel on sacrificial layer 750, is also clearly discernible. SiN is used in the CMOS process flow to manufacture spacers around the gate electrode. These spacers are needed for subsequent self-adjusted implantation of the drain and source regions. For the pressure sensor, SiN is used as the diaphragm layer which assumes the mechanical functionality in the final sensor element. FIG. 7e shows a top view of a possible implementation of the pressure sensor. The central circular region represents the region deflectable by pressure. Terminal 780 of upper electrode 785 and terminal 770 of lower electrode 725 as well as etching access 765 are also shown. As illustrated on the basis of FIG. 7g, in the next method steps, SiO₂ insulation layers 800, 810, 820 and 830 and metal layers 790, 835, 840 and 845, which are used for wiring the CMOS elements, are deposited and structured in the next method steps in alternation using a TEOS process. The metal levels typically have a layer thickness of 600 nm (e.g., in the case of metal layer 790) to 1000 nm (e.g., for metal layer 840). A preferred process variant would leave the SiO₂ standing in the pressure sensor area but would remove the metal layers. It is also conceivable here for a few or individual SiO₂ layers to be opened to reduce the topography over the pressure sensor and simplify the subsequent exposure of etching access 765 via access 860 and/or the SiN diaphragm via access 870. After deposition of the wiring and insulation levels, access 860 to etching access 765 must first be opened and later also access 870 to the diaphragm. The etching access as well as the diaphragm area are both freed of the SiO₂ layers above them by combined wet/dry etching. The prerequisite for this is adequate selectivity of the etching step with respect to SiN. Second polysilicon layer 745 above etching access 765 and silicon-containing sacrificial layer 750 over the resulting etching channel are then dissolved out with the help of a dry chemical (plasmaless) etching method (e.g., ClF₃ etching process). This results in formation of a cavity 900 suitable for pressure sensing beneath the diaphragm. Subsequent passivation by the CMOS process (e.g., via an approximately 600 nm thick layer 880 of SiO₂ in combination with an approximately 750 nm thick layer 890 of SiN, as illustrated in FIG. 7h) is used for the barometric cell method for sealing etching access 765. If deposition of passivation layers 880 and 890 on the diaphragm has an interfering effect in pressure sensing, these layers may be re-etched in a last step.

Alternatively, etching access 765 could also be opened first, sacrificial layer etching performed using ClF₃ and the etching access sealed again. Only then could access 870 to the diaphragm be exposed.

Another possibility of opening, i.e., exposing, the etching access and diaphragm is not to remove the metal layers of which wiring elements 790, 835, 840 and 845 are formed in the pressure gauge area in the previous CMOS process but to remove the SiO₂ passivation layers in a countermove (comparable to a via contact). The metal stack above the pressure gauge could then be etched by a wet chemical method in a highly selective process with respect to SiN. Etching of the sacrificial layer and sealing of the etching access then proceed as already described.

1-18. (canceled)

19. A method for manufacturing a micromechanically monolithically integrated capacitive sensor element for detection of a physical quantity, the manufacturing comprising the method steps of:
producing a first electrode on a semiconductor substrate;
producing a first layer on at least the first electrode;
applying a first sacrificial layer of a first sacrificial material above at least a portion of the first electrode;
producing a second layer on the first sacrificial layer;
producing a first through hole through the second layer to the first sacrificial layer;
producing a second electrode on the second layer;
sealing the first through hole using a second sacrificial material, the second sacrificial material in the area of the first through hole;
covering at least a portion of the second layer;
forming a second sacrificial layer;
applying a diaphragm layer to the second electrode and at least a portion of the second layer adjacent to the second electrode;
producing a second through hole through the diaphragm layer to the second sacrificial material;
dissolving out the first and second sacrificial material, preferably via a plasmaless etching method, through the first and the second through hole;
applying a third layer to the diaphragm layer, the third layer sealing the second through hole; and
sealing the second through hole to create a cavity in the area of the first sacrificial layer between the first and the second electrodes.

20. The method as recited in claim 19, wherein an insulating layer is applied to the semiconductor substrate before producing the first electrode.

21. The method as recited in claim 19, wherein:
the first electrode contains an n- or p-type conducting doped semiconductor material or polysilicon, and/or
the first layer contains oxide, nitride or TEOS, and/or
the first sacrificial material contains Si or SiGe, and/or
the second layer contains oxide, nitride or TEOS, and/or
the second electrode contains Si, SiGe or polysilicon, and/or
the second sacrificial material contains SiGe or polysilicon, and/or
the diaphragm layer contains nitride or oxide or a dielectric material, and/or
the third layer contains nitride.

22. The method as recited in claim 19, wherein
the first layer has a layer thickness of 40 nm to 250 nm, and/or
the first sacrificial layer has a layer thickness of 0.3 μm to 1 μm, and/or
the second layer has a layer thickness of 50 nm to 250 nm, and/or
the diaphragm layer has a layer thickness of 100 nm to 1000 nm.

23. The method as recited in claim 19, wherein the layer thickness of the third layer is selected to be greater than the layer thickness of the second sacrificial layer.

24. The method as recited in claim 19, wherein the layer thickness of the second sacrificial layer is selected as a function of the layer thickness of the second electrode, both layer thicknesses in particular being largely similar.

25. The method as recited in claim 19, wherein at least a portion of a circuit is produced preferably by a CMOS process on the micromechanical sensor element, this circuit being provided:
for contacting the sensor element and/or
for detecting and/or analyzing the sensor signals of the sensor element, the circuit being produced in particular before dissolving out the first and second sacrificial layers.

26. The method as recited in claim 19, wherein a fourth insulating layer is applied between the first and second layers, the fourth layer in particular having a layer thickness comparable to that of the first sacrificial layer and/or being situated at least partially between the first and second electrodes.

27. The method as recited in claim 19, wherein the etching process for dissolving out the first and second sacrificial layers is performed:
using a fluorinated etching material, in particular ClF₃ or XeF₂, and/or at a temperature between −20° C. and 60° C.

28. The method as recited in claim 19, wherein at least a third through hole is produced on the first layer to form supporting points in the first sacrificial layer, so that the cavity supported by posts is produced during dissolving of the first and second sacrificial layers by filling the at least one third through hole with the material
of the second electrode, and/or
of the diaphragm layer.

29. The method as recited in claim 19, wherein a third electrode is produced above the second electrode, the third electrode:
being electrically insulated from the second electrode and covering at least the first and second electrodes;
the third electrode:
containing polysilicon or a metal, and/or
being structured like a mesh grating.

30. The method as recited in claim 19, wherein a mass element having a defined mass is applied to the diaphragm above the first electrode and the second electrode, the mass element being produced by a local deposition method, a dispensing method, a screen printing method or a micromechanical structuring method.

31. The method as recited in claim 30, wherein multiple diaphragm cells made up of a first electrode and a second electrode, a cavity between the electrodes, and a diaphragm are produced on the semiconductor substrate, a mass element of different sizes being applied to each diaphragm.

32. A micromechanical device, comprising:
a micromechanically monolithically integrated capacitive sensor element for detecting a physical quantity, in particular for detecting a pressure quantity and/or an acceleration quantity, the sensor element having at least:
a first electrode,
a second electrode,
a diaphragm, and
a cavity.

33. The micromechanical device as recited in claim 32, wherein the micromechanical device also has a reference element in addition to the micromechanically monolithically integrated sensor element, the diaphragm of the reference element having supporting areas by which an electrically insulated mechanical connection of the diaphragm and/or the second electrode to the substrate is produced.

34. The micromechanical device as recited in claim 32, wherein for detection of the physical quantity:
the second electrode has the ground potential and the physical quantity is detected as a function of the charges on the first electrode, or
the third electrode has the ground potential and the physical quantity is detected as a function of the charge on one of the two other electrodes.

35. The micromechanical device as recited in claim 33, wherein the diaphragm has a mass element above the cavity for detection of an acceleration quantity, the mass element in particular being connected rigidly to a layer forming the diaphragm.

36. The micromechanical device as recited in claim 35, wherein a plurality of diaphragm cells made up of a first and second electrode, a cavity between them and a diaphragm are produced on the semiconductor substrate, a mass element of a different size being assigned to each diaphragm.
